(19) United States
(12) Patent Application Publication
(10) Pub. No.: US 2024/0096537 A1
(43) Pub. Date: Mar. 21, 2024

(54) PRINTED WIRING BOARD

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Yukie TSUDA, Osaka (JP); Koji NITTA, Osaka (JP); Kou NOGUCHI, Osaka (JP)

(73) Assignees: SUMITOMO ELECTRIC INDUSTRIES, LTD., Osaka (JP); SUMITOMO ELECTRIC PRINTED CIRCUITS, INC., Shiga (JP)

(21) Appl. No.: 18/275,001

(22) PCT Filed: Aug. 17, 2022
(86) PCT No.: PCT/JP2022/031070

§ 371 Date: Jul. 29, 2023

(30) Foreign Application Priority Data
Aug. 30, 2021 (JP) 2021-140101

(51) Int. Cl. H01F 17/00

(52) U.S. Cl. CPC H01F 17/0013

(57) ABSTRACT

A printed wiring board includes a base film having a main surface, a coil wiring formed on the main surface, and a first connection land and a second connection land connected to one end and another end of the coil wiring, respectively. The main surface includes a first main surface and a second main surface opposite to the first main surface. The coil wiring includes a first coil wiring formed in a spiral shape on the first main surface, and a second coil wiring formed in a spiral shape on the second main surface and electrically connected to the first coil wiring. The first connection land and the second connection land are formed on the second main surface. The number of turns of the first coil wiring is more than the number of turns of the second coil wiring.

### TECHNICAL FIELD

The present disclosure relates to a printed wiring board. This application claims priority based on Japanese Patent Application No. 2021-140101 filed on Aug. 30, 2021, and the entire contents of the Japanese patent application are incorporated herein by reference.

### BACKGROUND

For example, Japanese Unexamined Patent Application Publication No. 2016-9854 (PTL 1) describes a printed wiring board. The printed wiring board described in PTL 1 includes a base film and a wiring. The base film has a first main surface and a second main surface opposite to the first main surface. The wiring includes a first wiring disposed on the first main surface and a second wiring disposed on the second main surface. The first wiring and the second wiring are electrically connected to each other via a plating layer disposed on an inner wall surface of a through hole formed in the base film. The first wiring and the second wiring are wound in a spiral shape to form a coil.

### PRIOR ART DOCUMENT

### Patent Literature

PTL 1: Japanese Unexamined Patent Application Publication No. 2016-9854

### SUMMARY

A printed wiring board of the present disclosure includes a base film having a main surface, a coil wiring formed on the main surface, and a first connection land and a second connection land connected to one end and another end of the coil wiring, respectively. The main surface includes a first main surface and a second main surface being a surface opposite to the first main surface. The coil wiring includes first coil wiring formed in a spiral shape on the first main surface, and second coil wiring formed in a spiral shape on the second main surface and electrically connected to the first coil wiring. The first connection land and the second connection land are formed on the second main surface. The number of turns of the first coil wiring is more than the number of turns of the second coil wiring.

### BRIEF DESCRIPTION OF THE DRAWINGS

FIG. 1 is a plan view of a printed wiring board 100.

FIG. 2 is a bottom plan view of printed wiring board 100.

FIG. 3 is a cross-sectional view taken along line III-III of FIG. 1.

FIG. 4 is a cross-sectional view taken along line IV-IV of FIG. 1.

FIG. 5 is a cross-sectional view taken along line V-V of FIG. 1.

FIG. 6 is a schematic diagram of an actuator using printed wiring board 100.

FIG. 7 is a flow chart showing a method of manufacturing printed wiring board 100.

FIG. 8 is a cross-sectional view showing a seed-layer formation step S2.

FIG. 9 is a cross-sectional view showing a resist formation step S3.

FIG. 10 is a cross-sectional view showing a first electrolytic plating step S4.

FIG. 11 is a cross-sectional view showing a resist removal step S5.

FIG. 12 is a cross-sectional view showing an etching step S6.

### DETAILED DESCRIPTION

### Problems to be Solved by Present Disclosure

In the printed wiring board described in PTL 1, one end and another end of the wiring need to be electrically connected to the connection land. It is conceivable that the connection lands are disposed on a separate printed wiring board. However, in this case, since a printed wiring board other than the printed wiring board described in PTL 1 is required, the thickness of the coil device using the printed wiring board described in PTL 1 increases.

The present disclosure has been made in view of the problems of the prior art as described above. The present disclosure provides a printed wiring board in which the thickness of the coil device can be reduced.

### Advantageous Effects of Present Disclosure

According to the printed wiring board of the present disclosure, it is possible to reduce the thickness of the coil device.

### DESCRIPTION OF EMBODIMENTS OF PRESENT DISCLOSURE

First, embodiments of the present disclosure will be listed and explained.
(1) A printed wiring board includes a base film having a main surface, a coil wiring formed on the main surface, and a first connection land and a second connection land connected to one end and another end of the coil wiring, respectively. The main surface includes a first main surface and a second main surface opposite to the first main surface. The coil wiring includes a first coil wiring formed in a spiral shape on the first main surface, and a second coil wiring formed in a spiral shape on the second main surface and electrically connected to the first coil wiring. The first connection land and the second connection land are formed on the second main surface. The number of turns of the first coil wiring is more than the number of turns of the second coil wiring.

According to the printed wiring board of (1), it is possible to reduce the thickness of the coil device.
(2) In the printed wiring board according to (1), the number of the turns of the first coil wiring may be 1.1 times to 4.3 times the number of the turns of the second coil wiring.
(3) In the printed wiring board according to (1) or (2), the first coil wiring may be longer than the second coil wiring.
(4) In the printed wiring board according to (1) to (3), an area ratio of the first coil wiring may be larger than an area ratio of the second coil wiring.
(5) In the printed wiring board according to (3), a length of the first coil wiring may be 1.1 times to 3.0 times a length of the second coil wiring.
(6) In the printed wiring board according to (4), the area ratio of the first coil wiring may be 1.1 times to 2.5 times the area ratio of the second coil wiring.
(7) In the printed wiring board according to (1) to (6), the first main surface may be disposed to face the magnet.

According to the printed wiring board of the above (7), it is possible to secure the Lorentz force of the coil device while reducing the thickness of the coil device.
(8) In the printed wiring board according to (1) to (7), an interval between two adjacent portions of the coil wiring may be 20 μm or less.

According to the printed wiring board of the above (8), since it is possible to improve the number of turns (length, area ratio) of the first coil wiring and the number of turns (length, area ratio) of the second coil wiring, it is possible to secure the Lorentz force of the coil device while reducing the thickness of the coil device.

### DETAILS OF EMBODIMENTS OF PRESENT DISCLOSURE

The details of embodiments of the present disclosure will now be described with reference to the drawings. In the following drawings, the same or corresponding portions are denoted by the same reference numerals, and redundant description will not be repeated.

### (Configuration of Printed Wiring Board According to Embodiment)

Hereinafter, a configuration of a printed wiring board (referred to as “printed wiring board 100”) according to an embodiment will be described.

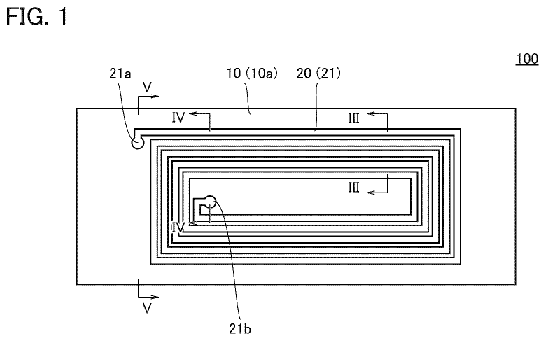

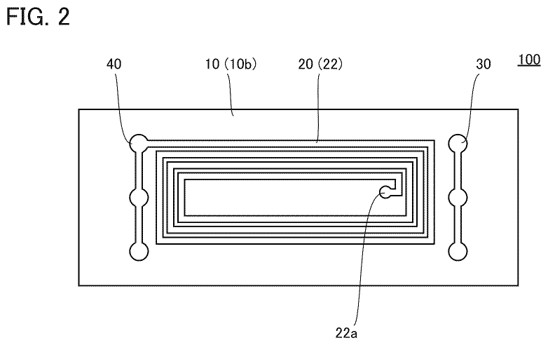

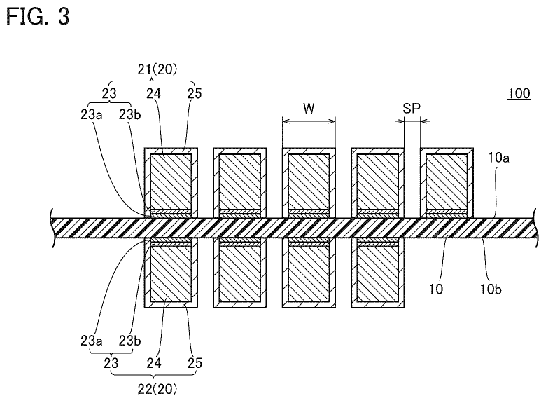

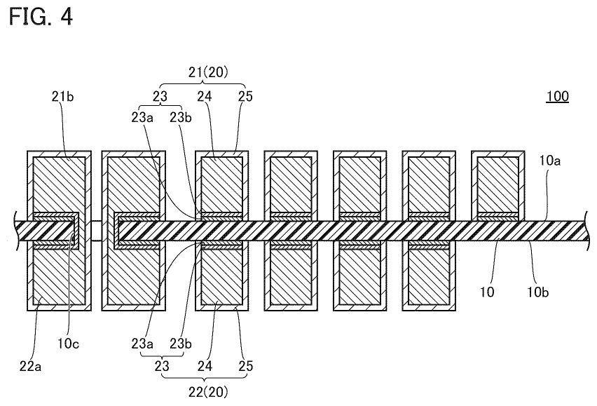

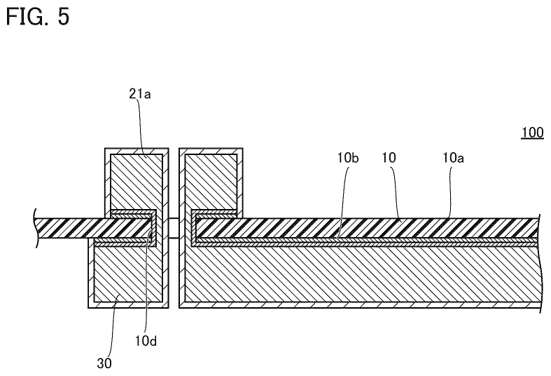

FIG. 1 is a plan view of a printed wiring board 100. FIG. 2 is a bottom plan view of printed wiring board 100. FIG. 2 shows printed wiring board 100 viewed from the opposite side of FIG. 1. FIG. 3 is a cross-sectional view taken along line III-III of FIG. 1. FIG. 4 is a cross-sectional view taken along line IV-IV of FIG. 1. FIG. 5 is a cross-sectional view taken along line V-V of FIG. 1. As shown in FIGS. 1 to 5, printed wiring board 100 includes a base film 10, a coil wiring 20, a first connection land 30 and a second connection land 40. Printed wiring board 100 functions as a coil device.

Base film 10 has a first main surface 10a and a second main surface 10b. First main surface 10a and second main surface 10b constitute end surfaces of base film 10 in the thickness direction. Second main surface 10b is a surface opposite to first main surface 10a. Base film 10 is formed of an insulating material having flexibility. Specific examples of the material constituting base film 10 include polyimide, polyethylene terephthalate, and fluororesin.

The thickness of base film 10 is, for example, 80 μm or less. The thickness of base film 10 is preferably 50 μm or less. The thickness of base film 10 is preferably 20 μm or less. The thickness of base film 10 is the distance between first main surface 10a and second main surface 10b.

A through hole 10c and a through hole 10d are formed in base film 10. Through hole 10c and through hole 10d penetrate base film 10 along the thickness direction.

Coil wiring 20 is disposed on the main surface of base film 10. Coil wiring 20 includes a first coil wiring 21 and a second coil wiring 22. First coil wiring 21 is disposed on first main surface 10a. Second coil wiring 22 is disposed on second main surface 10b. First coil wiring 21 and second coil wiring 22 are electrically connected to each other.

First coil wiring 21 is wound in a spiral shape when viewed from first main surface 10a side along the thickness direction of base film 10. From another point of view, first coil wiring 21 constitutes a coil (first coil). One end of first coil wiring 21 is outside the first coil. The other end of first coil wiring 21 is inside the first coil. One end of first coil wiring 21 is a land 21a. The other end of first coil wiring 21 is a land 21b.

Second coil wiring 22 is wound in a spiral shape when viewed from second main surface 10b side along the thickness direction of base film 10. From another point of view, second coil wiring 22 constitutes a coil (second coil). One end of second coil wiring 22 is inside the second coil. The other end of second coil wiring 22 is outside the second coil. One end of second coil wiring 22 is a land 22a. Land 22a is electrically connected to land 21b by a second layer 23b, a first electrolytic plating layer 24, and a second electrolytic plating layer 25 which are disposed on the inner wall surface of through hole 10c. Land 22a may be electrically connected to land 21b by filling first electrolytic plating layer 24 and second electrolytic plating layer 25 in through hole 10c.

Coil wiring 20 (first coil wiring 21 and second coil wiring 22) includes a seed layer 23, first electrolytic plating layer 24, and second electrolytic plating layer 25.

Seed layer 23 is disposed on the main surfaces (first main surface 10a and second main surface 10b) of base film 10. Seed layer 23 includes a first layer 23a and second layer 23b.

First layer 23a is disposed on the main surface (first main surface 10a and second main surface 10b) of base film 10. First layer 23a is, for example, a sputtered layer (a layer formed by sputtering) formed of a nickel-chromium alloy. Second layer 23b is disposed on first layer 23a. Second layer 23b is, for example, an electroless plating layer formed of copper (a layer formed of electroless plating). Second layer 23b is also formed on the inner wall surfaces of through hole 10c and through hole 10d.

First electrolytic plating layer 24 is a layer formed by electrolytic plating. First electrolytic plating layer 24 is disposed on seed layer 23 (second layer 23b). First electrolytic plating layer 24 is formed of, for example, copper. First electrolytic plating layer 24 is also disposed on second layer 23b on the inner wall surfaces of through hole 10c and through hole 10d.

Second electrolytic plating layer 25 is a layer formed by electrolytic plating. Second electrolytic plating layer 25 covers first electrolytic plating layer 24. More specifically, second electrolytic plating layer 25 is disposed on seed layer 23 and on the side surface and the upper surface of first electrolytic plating layer 24. Second electrolytic plating layer 25 is also disposed on first electrolytic plating layer 24 on the inner wall surfaces of through hole 10c and through hole 10d.

The interval between adjacent portions of coil wiring 20 is referred to as an interval SP. The width of coil wiring 20 is referred to as a width W. Interval SP is, for example, 20 μm or less. Interval SP is preferably 15 μm or less. Interval SP is more preferably 10 μm or less. Interval SP is preferably smaller than width W. Width W is, for example, 25 μm or less. The height of coil wiring 20 is preferably greater than width W. The height of coil wiring 20 is, for example, 35 μm or more.

In the measurement of interval SP and width W, firstly, five measurement points are set in the length direction of coil wiring 20. The interval between these measurement points is set to be equal in the length direction of coil wiring 20. However, the intervals of these measurement points may be substantially equal intervals, and may not be strictly equal intervals. Secondly, at each measurement point, an interval between adjacent portions of coil wiring 20 and a width of coil wiring 20 are measured in a cross-section perpendicular to the length direction of coil wiring 20. Then, the average values of the measured values are set as interval SP and width W.

The number of turns of first coil wiring 21 is more than the number of turns of second coil wiring 22. The number of turns of first coil wiring 21 is preferably 1.1 times to 4.3 times the number of turns of second coil wiring 22.

The number of turns of first coil wiring 21 is an average value of the number of first coil wiring 21 on one side from the center of the coil and the number of first coil wiring 21 on the other side from the center of the coil in a cross section orthogonal to the longitudinal direction of the coil constituted by first coil wiring 21. The number of turns of second coil wiring 22 is calculated in the same way as first coil wiring 21. In the example shown in FIGS. 1 and 2, the number of turns of first coil wiring 21 is 5, and the number of turns of second coil wiring 22 is 3.5.

First coil wiring 21 is longer than second coil wiring 22. The length of first coil wiring 21 is a distance between one end of first coil wiring 21 and the other end of first coil wiring 21. The length of second coil wiring 22 is a distance between one end of second coil wiring 22 and the other end of second coil wiring 22. The length of first coil wiring 21 is preferably 1.1 times to 3.0 times the length of second coil wiring 22. By setting the ratio between the length of first coil wiring 21 and the length of second coil wiring 22 in this manner, first coil wiring 21 and second coil wiring 22 can be set to a preferable number of turns.

The length of first coil wiring 21 is a length of first coil wiring 21 between lands at both ends of first coil wiring 21. More specifically, the length of first coil wiring 21 is the length of first coil wiring 21 between land 21a and land 21b. The length of second coil wiring 22 is a length of second coil wiring 22 between lands at both ends of second coil wiring 22. More specifically, the length of second coil wiring 22 is the length of second coil wiring 22 between land 22a and second connection land 40.

The area ratio of first coil wiring 21 is greater than the area ratio of second coil wiring 22. The area ratio of first coil wiring 21 is preferably 1.1 times to 2.5 times the area ratio of second coil wiring 22. By setting the ratio between the area ratio of first coil wiring 21 and the area ratio of second coil wiring 22 in this manner, first coil wiring 21 and second coil wiring 22 can be set to a preferable number of turns.

The area ratio of first coil wiring 21 is a value obtained by dividing a sum of an area of first coil wiring 21 and an area of first main surface 10a between adjacent portions of first coil wiring 21 by a total area of first main surface 10a when viewed from first main surface 10a side along the thickness direction of base film 10. The area ratio of second coil wiring 22 is a value obtained by dividing a sum of an area of second coil wiring 22 and an area of second main surface 10b between adjacent portions of second coil wiring 22 by a total area of second main surface 10b when viewed from second main surface 10b side along the thickness direction of base film 10.

First connection land 30 and second connection land 40 are disposed on second main surface 10b. First connection land 30 is electrically connected to land 21a by second layer 23b, first electrolytic plating layer 24, and second electrolytic plating layer 25 which are disposed on the inner wall surface of through hole 10d. First connection land 30 may be electrically connected to land 21a by filling first electrolytic plating layer 24 and second electrolytic plating layer 25 in through hole 10d.

Second connection land 40 is connected to another end of second coil wiring 22. In this way, first connection land 30 and second connection land 40 are electrically connected to one end and another end of coil wiring 20, respectively.

Printed wiring board 100 is electrically connected to an external device at first connection land 30 and second connection land 40. Accordingly, coil wiring 20 is energized, and the first coil and the second coil generate a magnetic field. Like coil wiring 20, first connection land 30 and second connection land 40 are composed of seed layer 23, first electrolytic plating layer 24, and second electrolytic plating layer 25.

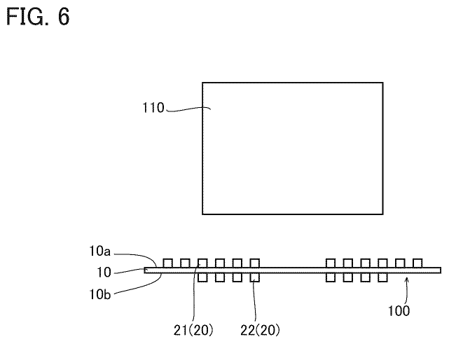

Printed wiring board 100 constitutes an actuator together with, for example, a magnet 110. FIG. 6 is a schematic diagram of an actuator using printed wiring board 100. As shown in FIG. 6, in printed wiring board 100, first main surface 10a is preferably disposed to face magnet 110.

### (Method of Manufacturing Printed Wiring Board According to Embodiment)

Hereinafter, a method of manufacturing printed wiring board 100 will be described.

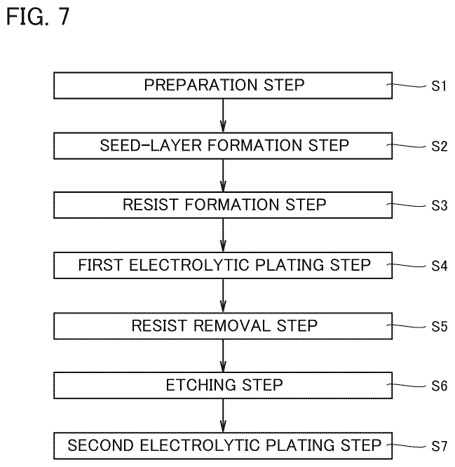

Printed wiring board 100 is manufactured using, for example, a semi-additive method. FIG. 7 is a flow chart showing a method of manufacturing printed wiring board 100. As shown in FIG. 7, the method of manufacturing printed wiring board 100 includes a preparation step S1, a seed-layer formation step S2, a resist formation step S3, a first electrolytic plating step S4, a resist removal step S5, an etching step S6, and a second electrolytic plating step S7.

In preparation step S1, base film 10 is prepared. Coil wiring 20 is not formed on the main surface of the base film prepared in preparation step S1.

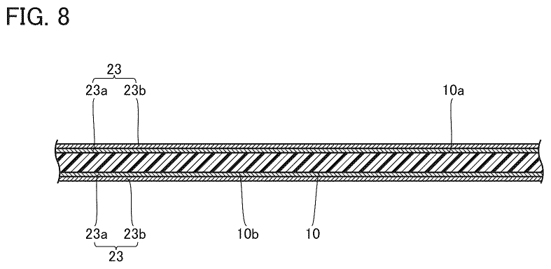

FIG. 8 is a cross-sectional view showing seed-layer formation step S2. In seed-layer formation step S2, seed layer 23 is formed. In seed-layer formation step S2, firstly, first layer 23a is formed by sputtering, for example. In seed-layer formation step S2, secondly, second layer 23b is formed by, for example, electroless plating.

Although not shown, through hole 10c and through hole 10d are formed after first layer 23a is formed and before second layer 23b is formed. Through hole 10c and through hole 10d are formed by using, for example, a laser or a drill. Therefore, second layer 23b is formed on the inner wall surfaces of through hole 10c and through hole 10d.

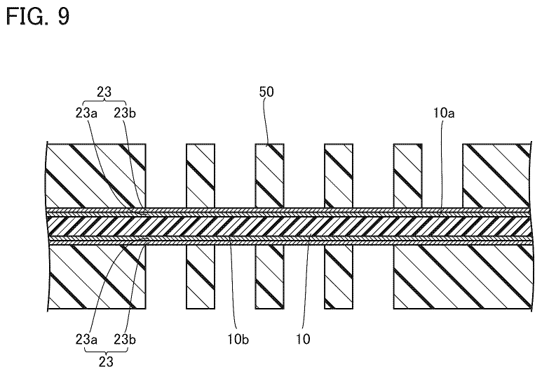

FIG. 9 is a cross-sectional view showing resist formation step S3. As shown in FIG. 9, in resist formation step S3, a resist 50 is formed on seed layer 23. Resist 50 is formed by applying a photosensitive organic material and patterning the applied photosensitive organic material by exposure and development. Resist 50 may be formed by attaching a dry film resist on seed layer 23 and patterning the attached dry film resist by exposure and development. Resist 50 has an opening. Seed layer 23 is exposed from the opening of resist 50.

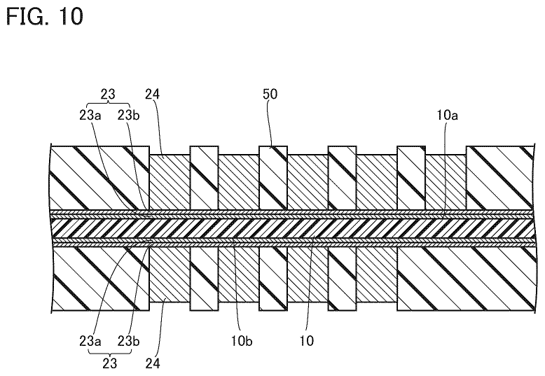

FIG. 10 is a cross-sectional view showing first electrolytic plating step S4. As shown in FIG. 10, in first electrolytic plating step S4, first electrolytic plating layer 24 is formed. In first electrolytic plating step S4, first electrolytic plating layer 24 is grown on seed layer 23 exposed from the opening of resist 50 by energizing seed layer 23 in the plating solution. Although not shown, first electrolytic plating layer 24 is also grown on second layer 23b on through hole 10c and through hole 10d.

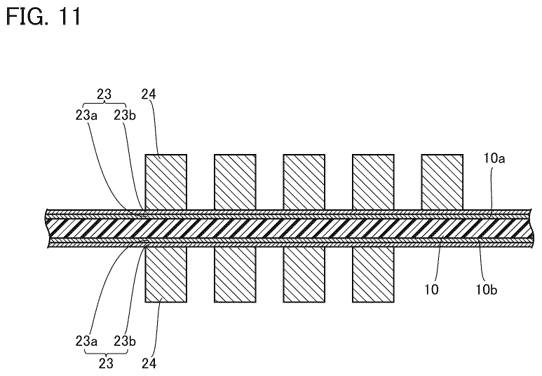

FIG. 11 is a cross-sectional view showing resist removal step S5. As shown in FIG. 11, in resist removal step S5, resist 50 is removed. After resist 50 is removed, seed layer 23 is exposed between adjacent first electrolytic plating layers 24.

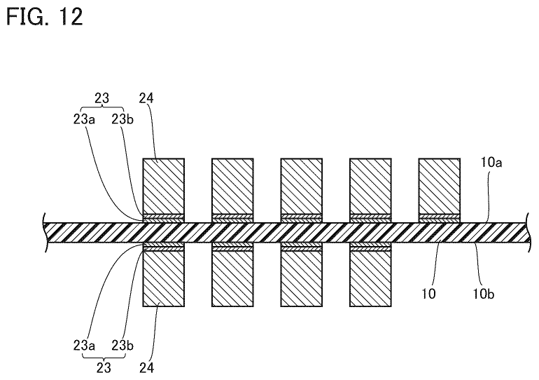

FIG. 12 is a cross-sectional view showing etching step S6. As shown in FIG. 12, in etching step S6, seed layer 23 exposed between adjacent first electrolytic plating layers 24 is removed by etching.

In etching step S6, firstly, second layer 23b is etched. The etching of second layer 23b is performed by supplying an etchant between adjacent first electrolytic plating layers 24. The etchant is selected so that the etching rate is controlled not by diffusion of the reactive species in the etchant to the vicinity of the etching target but by reaction between the reactive species in the etchant and the etching target.

More specifically, as the etchant, an etchant having a dissolution reaction rate of 1.0 μm/min or less with respect to the material (i.e., copper) constituting second layer 23b is used. Specific examples of the etchant include sulfuric acid hydrogen peroxide aqueous solutions and sodium peroxyodisulfate aqueous solutions. The dissolution reaction rate of the etching solution is measured based on the weight of copper reduced after etching and the etching time.

In etching step S6, secondly, first layer 23a is etched. When first layer 23a is etched, the etching solution is switched. As the etchant after the switching, an etchant having a high selection ratio with respect to the material constituting first layer 23a (i.e., nickel-chromium alloy) is used. Therefore, after the etching solution is switched, etching of first electrolytic plating layer 24 is less likely to proceed.

In second electrolytic plating step S7, second electrolytic plating layer 25 is formed. In second electrolytic plating step S7, second electrolytic plating layer 25 is grown so as to cover seed layer 23 and first electrolytic plating layer 24 by energizing seed layer 23 and first electrolytic plating layer 24 in the plating solution. Although not shown, second electrolytic plating layer 25 is also grown on first electrolytic plating layer 24 on through hole 10c and through hole 10d. As described above, printed wiring board 100 having the structure shown in FIGS. 1 to 5 is manufactured.

### (Effects of Printed Wiring Board According to Embodiment)

Hereinafter, effects of printed wiring board 100 will be described.

In order to energize coil wiring 20, first connection land 30 and second connection land 40 need to be electrically connected to coil wiring 20. As a method of disposing first connection land 30 and second connection land 40, it is conceivable to dispose first connection land 30 and second connection land 40 on a printed wiring board different from printed wiring board 100. However, in this case, a printed wiring board different from printed wiring board 100 is required to constitute the coil device, and the thickness of the coil device increases.

In printed wiring board 100, since first connection land 30 and second connection land 40 are disposed on second main surface 10b, a printed wiring board other than printed wiring board 100 is not required to constitute the coil device. Therefore, the coil device can be configured by only printed wiring board 100, and the thickness of the coil device can be reduced.

In printed wiring board 100, since first connection land 30 and second connection land 40 are disposed on second main surface 10b, the number of turns of second coil wiring 22 is smaller than the number of turns of first coil wiring 21 (second coil wiring 22 is shorter than first coil wiring 21, the area ratio of second coil wiring 22 is smaller than the area ratio of first coil wiring 21).

However, as will be described later, in printed wiring board 100, since first main surface 10a is disposed to face magnet 110, it is possible to maintain the Lorentz force when used in the actuator despite the reduction of the number of turns (length, area ratio) of second coil wiring 22.

Conventionally, an etching solution having a high dissolution reaction rate with respect to the material constituting the seed layer (i.e., an etching solution in which the diffusion of the reactive species in the etching solution to the vicinity of the etching target controls the etching rate) has been used. When the distance between adjacent portions of coil wiring is reduced, the etchant is less likely to be supplied between adjacent portions of coil wiring 20. As a result, when the etching solution as described above is used, the etching variation with respect to the seed layer becomes large, and the etching amount increases in order to reliably remove the seed layer. Due to the above reasons, the distance between adjacent portions of the coil wiring cannot be reduced in the related art.

In printed wiring board 100, an etching solution having a low dissolution reaction rate with respect to the material constituting second layer 23b is used in etching step S6. As a result, the etching in etching step S6 is rate-controlled by the reaction between the reactive species in the etchant and the etching target, and even if the etchant is hardly supplied between adjacent first electrolytic plating layers 24, variations in the etching of second layer 23b are unlikely to occur.

Therefore, according to printed wiring board 100, the distance between adjacent portions of coil wiring 20 may be reduced, and the number of turns (length, area ratio) of first coil wiring 21 and second coil wiring 22 can be increased. As a result, according to printed wiring board 100, it is possible to maintain the Lorentz force when used in the actuator while reducing the thickness of the coil device.

### <Simulation>

A simulation was performed to confirm the effect of printed wiring board 100. In the simulation, while the number of turns of first coil wiring 21 and the number of turns of second coil wiring 22 are changed so that the sum of the number of turns of first coil wiring 21 and the number of turns of second coil wiring 22 is the same, the Lorentz force generated by printed wiring board 100 against magnet 110 is calculated.

TABLE 1

| | | Sam- | Sam- | Sam- | Sam- | Sam- |
|---|---|---|---|---|---|---|
| | | ple | ple | ple | ple | ple |
| | | 1 | 2 | 3 | 4 | 5 |
| Width W (μm) | | 25 | 25 | 25 | 25 | 25 |
| Interval SP (μm) | | 25 | 5 | 8 | 15 | 19 |
| Number of Turns of | | 16 | 26 | 24 | 20 | 18 |
| First Coil Wiring 21 | | | | | | |
| Number of Turns of | | 16 | 6 | 8 | 12 | 14 |
| Second Coil Wiring 22 | | | | | | |
| Number of Turns of First | | 1 | 4.3 | 3 | 1.67 | 1.29 |
| Coil Wiring 21/Number of | | | | | | |
| Turns of Second Coil Wiring 22 | | | | | | |
| Lorentz | Thickness of Base | 13.0 | 14.4 | 14.3 | 14.0 | 13.7 |
| Force | Film 10: 12.5 μm | | | | | |
| (mN/ | Thickness of Base | 12.2 | 13.9 | 13.7 | 13.2 | 12.8 |
| (mm · A)) | Film 10: 75.0 μm | | | | | |

In the simulation, samples 1 to 5 were provided as samples of printed wiring board 100. In Sample 1, the number of turns of first coil wiring 21 and the number of turns of second coil wiring 22 were made equal. On the other hand, in the samples 2 to 5, the number of turns of first coil wiring 21 was made larger than the number of turns of second coil wiring 22. In samples 1 to 5, first main surface 10a was disposed to face magnet 110. Further, in each sample, two kinds of thicknesses were applied as the thickness of base film 10.

In the samples 1 to 5, width W was constant at 25 μm. In the samples 2 to 5, interval SP was sequentially decreased so as to increase the number of turns of first coil wiring 21.

In the samples 2 to 5, although the sum of the number of turns of first coil wiring 21 and the number of turns of second coil wiring 22 was the same, the Lorentz force generated against magnet 110 was larger than that of the sample 1. From this comparison, it is clear that the Lorentz force when used in the actuator can be maintained by making the number of turns of first coil wiring 21 larger than the number of turns of second coil wiring 22 and disposing first main surface 10a to face magnet 110.

In Samples 2 to 5, as the value obtained by dividing the number of turns of first coil wiring 21 by the number of turns of second coil wiring 22 increased, the Lorentz force generated against magnet 110 increased. From this, it became clear that the Lorentz force when used in an actuator is further improved by increasing the value obtained by dividing the number of turns of first coil wiring 21 by the number of turns of second coil wiring 22.

In Sample 2 to Sample 5, when the thickness of base film 10 was small, the Lorentz force generated against magnet 110 was larger than when the thickness of base film 10 was large. From this, it became clear that the Lorentz force when used in an actuator is further improved by reducing the thickness of base film 10.

### (Supplementary Notes)

The structure of the printed wiring board according to the present disclosure is described below.

### <Supplementary Note 1>

A printed wiring board comprising:
a base film having a main surface;
a coil wiring formed on the main surface; and
a first connection land and a second connection land connected to one end and another end of the coil wiring, respectively,
wherein the main surface includes a first main surface and a second main surface opposite to the first main surface,
wherein the coil wiring includes a first coil wiring formed in a spiral shape on the first main surface, and a second coil wiring formed in a spiral shape on the second main surface and electrically connected to the first coil wiring,
wherein the first connection land and the second connection land are formed on the second main surface, and
wherein the first coil wiring is longer than the second coil wiring.

According to the printed wiring board of Supplementary Note 1, since the first connection land and the second connection land can be formed on the second main surface by adjusting the length of the coil wiring, the thickness of the coil device can be reduced.

### <Supplementary Note 2>

The printed wiring board according to Supplementary Note 1, wherein a length of the first coil wiring is 1.1 times to 3.0 times a length of the second coil wiring.

### <Supplementary Note 3>

A printed wiring board comprising:
a base film having a main surface;
a coil wiring formed on the main surface; and
a first connection land and a second connection land connected to one end and another end of the coil wiring, respectively,
wherein the main surface includes a first main surface and a second main surface opposite to the first main surface,
wherein the coil wiring includes a first coil wiring formed in a spiral shape on the first main surface, and a second coil wiring formed in a spiral shape on the second main surface and electrically connected to the first coil wiring,
wherein the first connection land and the second connection land are formed on the second main surface, and
wherein an area ratio of the first coil wiring is larger than an area ratio of the second coil wiring.

According to the printed wiring board of Supplementary Note 3, since the first connection land and the second connection land can be formed on the second main surface by adjusting the area ratio of the coil wiring, it is possible to reduce the thickness of the coil device.

### <Supplementary Note 4>

The printed wiring board according to Supplementary Note 3, wherein the area ratio of the first coil wiring is 1.1 times to 2.5 times the area ratio of the second coil wiring.

It should be understood that the embodiments disclosed herein are illustrative in all respects and are not restrictive. The scope of the present invention is defined not by the embodiments described above but by the claims, and is intended to include all modifications within the meaning and scope equivalent to the claims.

### REFERENCE SIGNS LIST

10 base film, 10a first main surface, 10b second main surface, 10c through hole, 10d through hole, 20 coil wiring, 21 first coil wiring, 21a land, 21b land, 22 second coil wiring, 22a land, 23 seed layer, 23a first layer, 23b second layer, 24 first electrolytic plating layer, 25 second electrolytic plating layer, 30 first connection land, 40 second connection land, 50 resist, 100 printed wiring board, 110 magnet, S1 preparation step, S2 seed-layer formation step, S3 resist formation step, S4 first electrolytic plating step, S5 resist removal step, S6 etching step, S7 second electrolytic plating step, SP interval, W width.

1. A printed wiring board comprising:
a base film having a main surface;
a coil wiring formed on the main surface; and
a first connection land and a second connection land connected to one end and another end of the coil wiring, respectively,
wherein the main surface includes a first main surface and a second main surface opposite to the first main surface,
wherein the coil wiring includes a first coil wiring formed in a spiral shape on the first main surface, and a second coil wiring formed in a spiral shape on the second main surface and electrically connected to the first coil wiring,
wherein the first connection land and the second connection land are formed on the second main surface, and
wherein the number of turns of the first coil wiring is more than the number of turns of the second coil wiring.

2. The printed wiring board according to claim 1, wherein the number of the turns of the first coil wiring is 1.1 times to 4.3 times the number of the turns of the second coil wiring.

3. The printed wiring board according to claim 1, wherein the first coil wiring is longer than the second coil wiring.

4. The printed wiring board according to claim 1, wherein an area ratio of the first coil wiring is larger than an area ratio of the second coil wiring.

5. The printed wiring board according to claim 3, wherein a length of the first coil wiring is 1.1 times to 3.0 times a length of the second coil wiring.

6. The printed wiring board according to claim 4, wherein the area ratio of the first coil wiring is 1.1 times to 2.5 times the area ratio of the second coil wiring.

7. The printed wiring board according to claim 1, wherein the first main surface is disposed to face a magnet.

8. The printed wiring board according to claim 1, wherein an interval between two adjacent portions of the coil wiring is 20 μm or less.
